(19) United States
(12) Patent Application Publication
(10) Pub. No.: US 2025/0365871 A1
(43) Pub. Date: Nov. 27, 2025

(54) APPARATUS FOR SEPARATING COOLING STRUCTURE FROM BASE BOARD

(71) Applicant: ZT Group Int'l, Inc., Secaucus, NJ (US)

(72) Inventors: Mahesh Kumar VARREY, Clifton, NJ (US); Chen AN, Bergenfield, NJ (US)

(73) Assignee: ZT Group Int'l, Inc., Secaucus, NJ (US)

(21) Appl. No.: 18/672,715

(22) Filed: May 23, 2024

(51) Int. Cl. H05K 3/22; G06F 1/20

(52) U.S. Cl. CPC H05K 3/22; G06F 1/20; H05K 2203/176

(57) ABSTRACT

The apparatus includes a body having one or more threaded holes and a pin for each threaded hole. Each pin has a screw configured to thread into one of the threaded holes and abutment surfaces configured to abut against loosened cooling structure mounting screws of a cooling structure. The apparatus further includes a plurality of arms coupled to the body with hooks configured to extend underneath the cooling structure. When the apparatus is mounted to the cooling structure, threading the screws into the threaded holes causes the body and arms to lift relative to the pins. Since the pins are abutted against the cooling structure mounting screws and the hooks are underneath the cooling structure, the cooling structure lifts from a base board on which it was mounted. By using multiple pins, even cooling structures with many interfaces can be easily separated.

### FIELD

This disclosure is directed to an apparatus for separating a cooling structure from a base board of a computing device.

### BACKGROUND

Many electronic components (e.g., circuits, processors, systems-on-chips (SOCs), amplifiers) are configured to interface with cooling structures (e.g., heat sinks, liquid cooling plates, cooling structures, and leak containment structures comprising multiple cooling structures) to dissipate heat generated by the electronic components. Often times the cooling structures can be difficult to separate from the electronic components due to adherence of thermal interface materials disposed between plates of the cooling structures and the electronic components and due to vacuum created by flatness of the plates and the electronic components. Separating cooling structures from electronic components can become exceedingly difficult when the cooling structures interface with multiple electronic components (e.g., a single cooling structure with a plurality of plates interfacing with a plurality of electronic components).

### SUMMARY

An apparatus for separating a cooling structure from a base board of a computing device is described herein. The apparatus includes a body including one or more threaded holes and one or more pairs of slots corresponding to the one or more threaded holes in a one-to-one correspondence. Each pair of slots of the one or more pairs of slots extends through the body and surrounds a threaded hole of the one or more threaded holes. The apparatus also includes one or more pins corresponding to the one or more threaded holes in a one-to-one correspondence. Each pin of the one or more pins has a through hole, a screw disposed in the through hole, where the screw is configured to thread into a threaded hole of the one or more threaded holes, legs configured to be disposed in respective slots of a pair of slots of the one or more pairs of slots, and abutment surfaces at respective ends of the legs configured to abut against cooling structure mounting screws of the cooling structure when the apparatus is installed on the cooling structure and the screw is threaded into the threaded hole. The apparatus further includes a plurality of arms coupled to the body. Each arm of the plurality of arms includes a hook configured to extend underneath the cooling structure when the apparatus is installed on the cooling structure.

A method of separating a cooling structure from a base board of a computing device is also described herein. The method includes loosening a plurality of cooling structure mounting screws that attach the cooling structure to the base board while keeping the cooling structure mounting screws partially threaded into the base board. The method also includes placing an apparatus over the cooling structure such that hooks of arms of the apparatus engage a cooling structure lower surface of the cooling structure and one or more pairs of slots of a base of the apparatus are aligned with the cooling structure mounting screws. The method further includes threading respective screws of one or more pins of the apparatus into respective threaded holes between the one or more pairs of slots of the base of the apparatus. The threading causing the arms and base of the apparatus to, once abutment surfaces of the pins are abutted against the cooling structure mounting screws, move relative to the mounting screws effective to separate the cooling structure from the base board. The method also includes removing the one or more pins. The method further includes fully loosening the cooling structure mounting screws and removing the cooling structure and the apparatus from the base board.

A system is also described herein. The system includes a cooling structure including one or more rows of cooling structure mounting locations configured to allow the cooling structure to be mounted to a base board of a computing device and an apparatus configured to separate the cooling structure from the base board. The apparatus includes a body having one or more threaded holes corresponding to the one or more rows of cooling structure mounting locations in a one-to-one correspondence and one or more pairs of slots corresponding to the one or more threaded holes and the one or more rows of cooling structure mounting locations in a one-to-one correspondence. Each pair of slots of the one or more pairs of slots extends through the body and surrounds a threaded hole of the one or more threaded holes. The apparatus also includes one or more pins corresponding to the one or more threaded holes and the one or more rows of cooling structure mounting locations in a one-to-one correspondence. Each pin of the one or more pins has a through hole, a screw disposed in the through hole, where the screw configured to thread into a threaded hole of the one or more threaded holes, legs configured to be disposed in respective slots of a pair of slots of the one or more pairs of slots and extend towards rows of cooling structure mounting locations of the cooling structure mounting locations, and abutment surfaces at ends of the legs configured to abut against cooling structure mounting screws disposed within the one or more rows of cooling structure mounting locations when the cooling structure is mounted to the base board, the apparatus is installed on the cooling structure, and the screw is threaded into the threaded hole. The apparatus further includes a plurality of arms coupled to the body. Each arm of the plurality of arms includes a hook configured to extend underneath the cooling structure when the apparatus is installed on the cooling structure.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a system containing a cooling structure and an apparatus for separating the cooling structure from a base board.

FIG. 2 illustrates an example of a computing system with a cooling structure mounted to a base board of the computing system.

FIG. 3 illustrates an example of an apparatus for separating a cooling structure from a base board.

FIG. 4 illustrates an example of a pin of an apparatus for separating a cooling structure from a base board.

FIG. 5 illustrates an example of a threaded hole disposed between a pair of slots of a body of an apparatus for separating a cooling structure from a base board.

FIGS. 6A and 6B illustrate an example of a cooling structure mounted to a base board with cooling structure mounting screws tightened and loosened.

FIGS. 7A and 7B illustrate an example of a cooling structure mounted to a base board with an apparatus for separating the cooling structure attached thereto.

FIGS. 8A and 8B illustrate an example of forces generated when an apparatus for separating a cooling structure from a base board is operated.

FIG. 9 illustrates an example method of removing a cooling structure from a base board.

### DETAILED DESCRIPTION

### Overview

Cooling structures can be difficult to remove from electronic components they are attached to due to adherence of thermal interface materials disposed between plates of the cooling structures and the electronic components and due to vacuum created by flatness of the plates and the electronic components. Removing cooling structures from electronic components can become difficult when the cooling structures interface with multiple electronic components (e.g., a single cooling structure with a plurality of plates interfacing with a plurality of electronic components).

Conventional techniques rely on a user removing mounting screws and pulling or prying the cooling structure from the electronic components or the base board. Doing so is not only difficult, it risks damaging the electronic components or the base board.

Described herein is an apparatus for separating a cooling structure from a base board of a computing device. The apparatus includes a body having one or more threaded holes and a pin for each threaded hole. Each pin has a screw configured to thread into one of the threaded holes and abutment surfaces configured to abut against loosened cooling structure mounting screws of a cooling structure. The apparatus further includes a plurality of arms coupled to the body with hooks configured to extend underneath the cooling structure. When the apparatus is mounted to the cooling structure, threading the screws into the threaded holes causes the body and arms to lift relative to the pins. Since the pins are abutted against the cooling structure mounting screws and the hooks are underneath the cooling structure, the cooling structure lifts from a base board on which is was mounted.

The apparatus allows the cooling structures to be lifted safely and effectively from the electronic components and base board. By using multiple pins, even cooling structures with large or multiple interfaces can be safely and easily separated.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example System

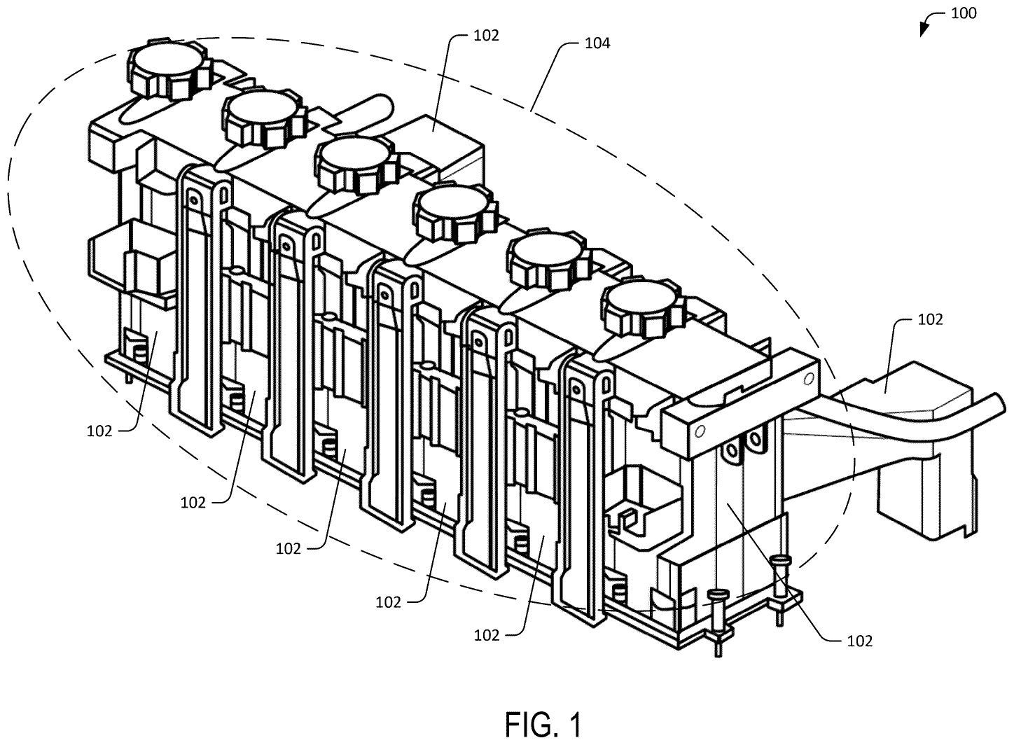

FIG. 1 illustrates an example of a system 100 with a cooling structure 102 and an apparatus 104 for separating the cooling structure 102 from a base board when the cooling structure 102 is attached thereto. The cooling structure 102 may be any type of air or liquid heat exchanger with one or more interface plates configured to interface with one or more electronic components (e.g., circuits, processors, amplifiers, SOCs, processing units). For example, the cooling structure 102 may be a liquid filled structure or leak containment structure with one or more interface plates. Although the apparatus 104 is configured to be removed from the cooling structure 102 in normal operation (e.g., such that a single instance of apparatus 104 may be used for other cooling structures 102 that are similar), the apparatus 104 may remain attached to the cooling structure 102 (or be an integral part of it).

The apparatus 104 may be configured for a certain configuration of the cooling structure 102 or the apparatus 104 may be configured for multiple configurations of the cooling structure 102. For example, the apparatus 104 may have various configurations that correspond to configurations of the cooling structure 102. Specifically, locations of mounting locations of the cooling structure 102 (as discussed further below) may dictate a configuration of the apparatus 104.

### Example Cooling Structure Mounting

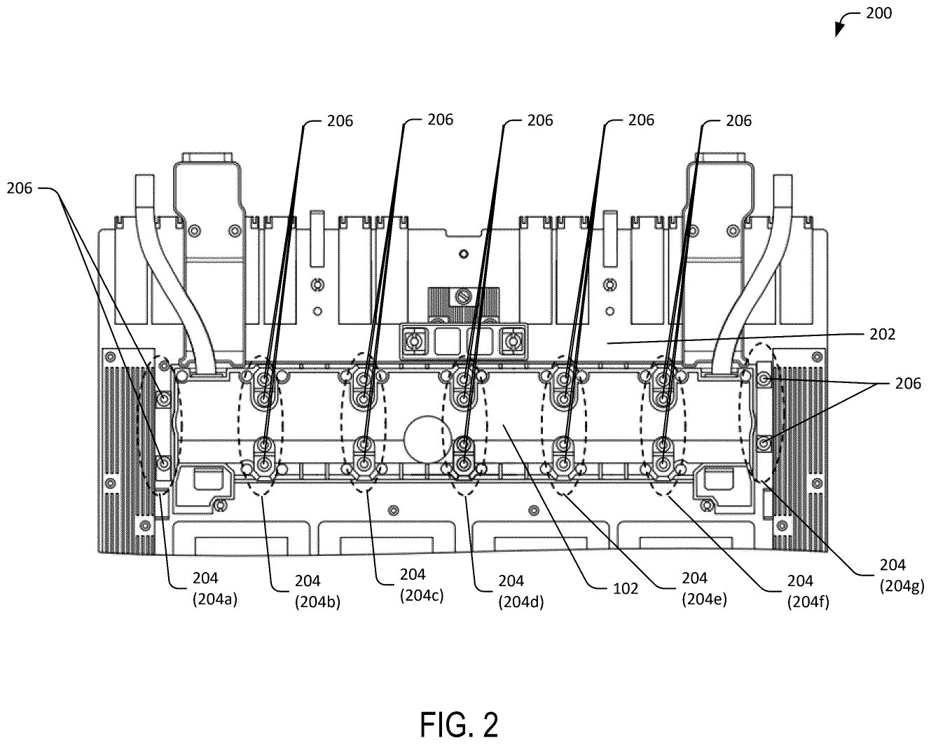

FIG. 2 illustrates an example of a computing system 200 with a cooling structure 102 attached to a base board 202 of the computing system 200. The computing system 200 may be any system (e.g., computer, server, rack component, blade) with one or more electronic components (e.g., processors) that require heat transfer and/or heat dissipation (e.g., away from the computing system 200 or to another portion of the computing system 200). The cooling structure 102 may contain one or more contact surfaces configured to interface with the electronic components.

The cooling structure 102 is mounted to the base board 202 and/or another structure of the computing system 200 (e.g., under the base board 202). For example, the cooling structure 102 contains one or more cooling structure mounting portions 204 (e.g., cooling structure mounting portions 204a-204g). The cooling structure mounting portions 204 are configured to receive cooling structure mounting screws 206. The cooling structure mounting portions 204 may comprise flat portions near a bottom of the cooling structure 102 configured to interface with washers or undersides of heads of the cooling structure mounting screws 206. Furthermore, the cooling structure mounting portions 204 may comprise depressions, grooves, or slots that extend from a top surface of the cooling structure 102 to the flat portions (e.g., to gain access to the cooling structure mounting screws 206).

The cooling structure mounting portions 204 may be organized in a linear array of rows. There may be any number of cooling structure mounting screws 206 in each row. In the illustrated example, the cooling structure mounting portions 204a and 204g are configured with two cooling structure mounting screws 206 each while the cooling structure mounting portions 204b-204f are configured with four cooling structure mounting screws 206 each.

Any configuration of the cooling structure mounting portions 204 and the cooling structure mounting screws 206 may be used without departing from the scope of this disclosure. Although the illustrated example shows seven linear arrays of cooling structure mounting screws 206 spaced relatively equally apart, the cooling structure 102 may contain any number of cooling structure mounting screws 206 in any locations. The apparatus 104 may be configured to adapt to many different locations of the cooling structure mounting screws 206.

### Example Apparatus

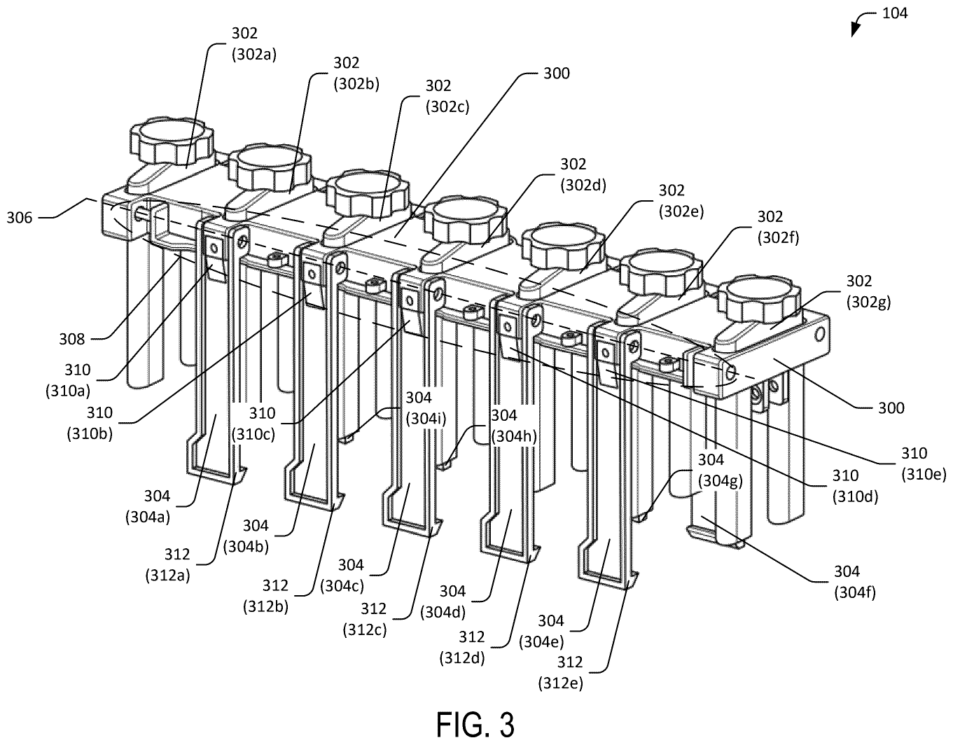

FIG. 3 illustrates an example of the apparatus 104. The apparatus 104 includes a body 300 and one or more pins 302 (e.g., pins 302a-302g) disposed therethrough. The pins 302 may be disposed in respective pairs of slots (e.g., slots 500 shown in FIG. 5) formed within the body 300 and be removable from the body 300.

Each pin 302 corresponds to a plurality of cooling structure mounting screws 206 and is configured to abut against a plurality of the cooling structure mounting screws 206. In the illustrated example, there are seven pins 302 corresponding to the seven linear arrays of cooling structure mounting screws 206. In some implementations, there may be less. For example, there may be four of pins 302 configured to interface with every other array of cooling structure mounting screws 206. In such implementations, the other cooling structure mounting screws 206 may be completely removed prior to installing the apparatus 104 or after the cooling structure 102 has been separated from the base board 202. In other words, not all of the cooling structure mounting screws 206 need to be used for the apparatus 104 to function properly. Furthermore, one or more cooling structure mounting screws 206 may be removed from a linear array without departing from the scope of this disclosure. For example, two out of four cooling structure mounting screws 206 of a linear array may be utilized. By at least two of the cooling structure mounting screws 206 (e.g., one on each side of the cooling structure 102) unwanted moments may be mitigated. As discussed above, the apparatus 104 may be configured for a variety of cooling structures 102. As such, different configurations/numbers of pins 302 may be utilized.

It should be noted that the pins 302 are arranged in a linear array because of the orientations of the linear arrays of cooling structure mounting screws 206 (e.g., they are in a linear array). In some implementations, the pins 302 may be offset laterally from one another, arranged in a 2D pattern/array, or any other configuration based on a configuration of an associated cooling structure 102.

Coupled to the body 300 are a plurality of arms 304 (e.g., arms 304a-304i). The arms 304 are configured to extend in a vertical direction (e.g., normal to a major surface of the body 300). A first side of the arms 304 is connected to the body 300. There may be any number of arms 304 depending upon a configuration of the cooling structure 102 and the base board 202. In general, there is at least one of the arms 304 on each side of the body 300. By having an arm 304 on each side of the body 300 unwanted moments may be mitigated. The arms 304 have a length (e.g., extend in a length direction) that corresponds to a height of the cooling structure 102. In some implementations, the arms 304 may have adjustable heights to adapt for multiple cooling structure heights.

The arms 304 are configured to deform or rotate away from each other. The deflection/rotation allows the apparatus 104 to be easily installed on and removed from the cooling structure 102. For example, the arms 304 may be configured to bend outwardly from each other, or, as in the illustrated example, be rotatably coupled to the body 300. The arms 304 are configured to rotate about respective rotation axes (e.g., rotation axis 306). A group of the arms 304 on one side of the body 300 may share a rotation axis. For example, arms 304a-304e may be configured to rotate about rotation axis 306 while arms 304g-304i (and other arms 304 that are occluded) may have another rotation axis. Arms 304 on a side of the body 300 may be configured to rotate independently or together. For example, arms 304a-304e may be coupled together in some implementations.

The apparatus 104 may contain one or more arm releases (e.g., arm release 308). The arm release 308 is configured to move a plurality of arms 304 that are disposed on a side of the body 300 in conjunction away from arms 304 on another side of the body. For example, the arm release 308 may comprise a long shaft that runs between the arms 304 and the body 300. The arm release 308 may share the rotation axis 306 or may have a separate rotation axis. In general, the rotation axis of the arm release 308 is substantially parallel with the rotation axis 306. When the arm release 308 is activated (e.g., rotated), the arms 304 that interface with the arm release 308 may be rotated in unison. The arm release 308 may have a feature designed to be manually operated (e.g., a portion configured to be interacted with by a finger or fingers of a user). The arm release 308 may also be configured as a stop for the arms 304. For example, the arm release 308 may be sandwiched between the arms 304 and the body 300, thus preventing the arms 304 from rotating further than vertical towards arms 304 disposed on another side of the body 300. The arm release 308 may be attached to the arms 304 or may simply interface with them (e.g., abut against them).

In order to maintain the arms 304 in a vertical orientation (e.g., to attach the apparatus 104 to the cooling structure 102 and to keep the apparatus 104 from prematurely detaching from the cooling structure 102), springs 310 (e.g., springs 310a-310e) may be utilized. The springs 310 may be configured to maintain pressure between the arms 304 and the arm release 308 (and thus, the body 300). In other words, the springs 310 may be configured to bias the arms 304 towards the body 300. The springs 310 may allow for temporary rotation of the arms 304 upon installation of the apparatus 104 to the cooling structure 102. If the arms 304 are attached to an arm release 308, a single spring may be attached to the arm release 308. In such implementations, the arms 304 may be pulled towards the base via the attachment of the arm release 308 to the arms 304.

At the end of the arms 304 (e.g., on a second side of the arms 304) are hooks 312 (e.g., hooks 312a-312e). The hooks 312 are configured to facilitate the deformation/rotation of the arms 304 upon installation of the apparatus 104 on the cooling structure 102 and to provide a holding force on an underside of the cooling structure 102 when the cooling structure 102 is being separated from the base board 202. To facilitate the deformation/rotation, each of the hooks 312 may contain a lead-in chamfer configured to, when a downward force is applied to the apparatus 104 as the apparatus 104 is placed on the cooling structure 102 cause an edge of the cooling structure 102 to engage the lead-in chamfer. As the edge doesn't move, the lead-in chamfers force the arms 304 to deform or rotate away from arms 304 on the other side of the body 300. After the lead-in chamfers have passed the edge, the arms 304 return to their prior shape/orientation with holding surfaces of the hooks 312 underneath the cooling structure 102.

### Example Pin

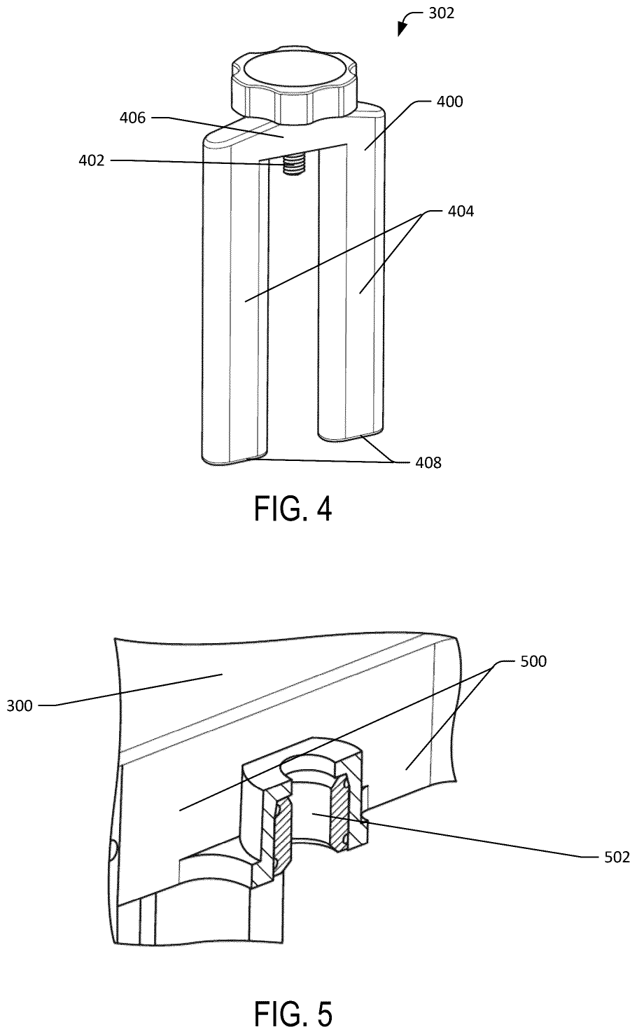

FIG. 4 illustrates an example of the pin 302. The pin 302 contains a pin body 400 and a screw 402. The pin 302 is configured to be movably mounted to the body 300 via the screw 402. The screw 402 is configured to be rotated by a user and may be any type of threaded device (e.g., a thumbscrew, a hand screw, a machine screw). The screw 402 is configured to interface with a threaded hole 502 disposed within the body 300. The screw 402 may be disposed within a through hole in the pin body 400 and may be held in place via washers or clips. The screw 402 is configured to rotate relative to the pin body 400.

The pin body 400 is generally a u-shaped structure (upside down) having two legs 404 and a bridge portion 406. The bridge portion 406 is configured to be arranged on one side of the pair of slots. The through hole is disposed in the bridge portion 406 and the legs 404 are configured to extend through a pair of slots 500 in the body 300 and into one of the cooling structure mounting portions 204. A length of the legs 404 may correspond to a height of the cooling structure 102 (at least a depth to the cooling structure mounting portions 204).

The legs 404 contain abutment surfaces 408 that are configured to indirectly or directly abut against the cooling structure mounting screws 206. Thus, each pin 302 contains an abutment surface 408 provided on one or each of the legs 404 of the pin 302. Depending upon a distance between the cooling structure mounting screws 206 and a configuration of the cooling structure mounting portion 204, a shape and/or relative dimensions of the pin body 400 may vary.

Regardless of configuration, the screw 402 is configured to interface with a portion of the body 300 and the pin body 400 is configured to straddle a portion of the cooling structure that connects two portions of a cooling structure mounting portion 204. The legs 404 are configured to extend down the cooling structure mounting portion 204 such that the abutment surfaces 408 can abut against the cooling structure mounting screws 206 within the cooling structure mounting portion 204.

### Example Pair of Slots and Threaded Hole

FIG. 5 illustrates an example of a portion of the body 300. The illustrated example shows the body 300 that defines a pair of slots 500 with a threaded hole 502 disposed therebetween. The pair of slots 500 may run through the body 300 and the threaded hole 502 may separate the pair of slots 500 and be oriented such that it has a same axis as a cut direction of the pair of slots 500. The screw 402 is configured to interface with the threaded hole 502 such that the legs 404 extend through the pair of slots 500 and straddle the threaded hole 502. The threaded hole 502 may be a threaded insert disposed within the body 300 (as shown) or a threaded hole 502 formed within the body 300.

### Alternative Configurations

Although the apparatus 104 has been described with the screw 402 attached to the pin 302 and the threaded hole 502 disposed within the pair of slots 500 as a separation mechanism, other configurations may be used without departing from the scope of this disclosure. For example, in some implementations, the screw 402 may be fixed to the body 300 (e.g., where the threaded hole 502 is) and extending upward. In such implementations, there may be a nut (e.g., hand nut) threaded onto the screw 402 once the pin body 400 is placed on the screw 402.

In some other implementations, there may not be a screw 402 at all. There are many ways of achieving a relative movement between the pin 302 and the body 300. For example, there may be a shaft extending upwards from between the pair of slots 500 and a cam lever configured to interface with the shaft and provide the necessary relative translation between the pin 302 and the body 300. Regardless of implementation, the pin 302 is configured to interface with a portion of the body 300 to provide a relative translation (e.g., up/down) between the pin 302 and the body 300.

In some implementations, the abutment surfaces 408 may directly interface with the base board 202. For example, the cooling structure mounting screws 206 may be removed and the abutment surfaces 408 may interface with the threaded holes in the base board 202 that the cooling structure mounting screws 206 were attached to. Furthermore, the pins 302 may be configured such that the abutment surfaces 408 are outside of a footprint of the cooling structure 102 and, thus, able to directly interface with the base board 202.

### Example Cooling Structure Mounting Screw Loosening

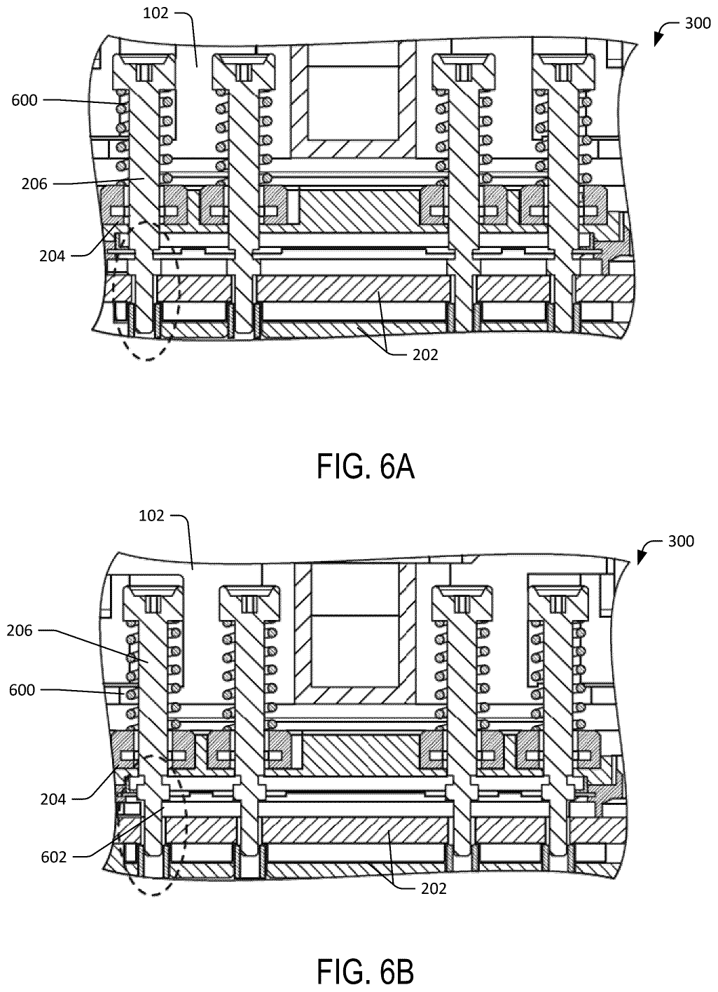

FIGS. 6A and 6B illustrate an example of a before (e.g., FIG. 6A) and after (e.g., FIG. 6B) loosening the cooling structure mounting screws 206 as part of separating the cooling structure 102 from the base board 202. In the illustrated example, screw springs 600 are used to secure the cooling structure 102 to the base board 202. The screw springs 600 provide a force between undersides of heads of the cooling structure mounting screws 206 and the cooling structure 102 (e.g., the cooling structure mounting portions 204). In some implementations, no screw springs 600 may be utilized. Instead, undersides of heads of the cooling structure mounting screws 206 (or washers interfacing therewith) may interface with the cooling structure mounting portions 204. Screw springs 600 may provide additional reliability (e.g., equal clamping pressure, less over-torquing risk, etc.) relative to straight bolting the cooling structure 102 to the base board 202.

Regardless of the configuration of the cooling structure mounting screws 206 (e.g., screw springs 600 or no screw springs 600), the cooling structure mounting screws 206 are loosened (e.g., partially threaded out) from the base board 202 in FIG. 6B. For example, the cooling structure mounting screws 206 may be loosened such that they move longitudinally while still being partially threaded into the base board 202. The partial threading allows for the cooling structure mounting screws 206 to provide a stable platform for the abutment surfaces 408 to rest on.

The loosening of the cooling structure mounting screws 206 may create a gap 602 between a screw limit (configured to simply be bottomed out to allow the screw springs 600 to provide the appropriate clamping force) and a top surface of the base board 202. If screw springs 600 are utilized (as shown) the loosening causes the screw springs 600 to provide less clamping force as the cooling structure mounting screws 206 move up. If screw springs 600 are not utilized, a gap may form between an underside of the cooling structure mounting screw 206 and the flat portion of the cooling structure mounting portion 204 (or somewhere between or around any intermediate pieces).

It should be noted that when screw springs 600 are utilized, it is possible to separate the cooling structure 102 from the base board 202 without loosening the cooling structure mounting screws 206. This is because the cooling structure 102 is free to lift from the base board 202 against the force of the screw springs 600 (e.g., the screw springs 600 would compress). Doing so, however, would not be productive as, when the pins 302 are removed, the assembly would close again. Loosening the cooling structure mounting screws 206 removes the clamping force provided by the screw springs 600.

### Example Attachment

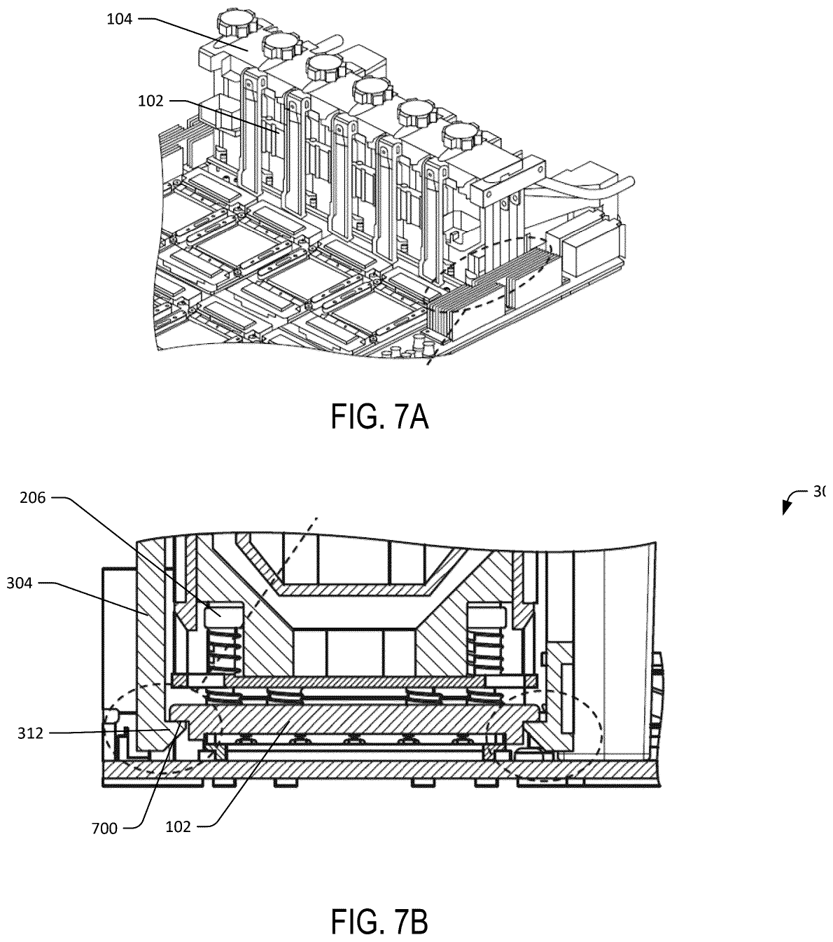

FIGS. 7A and 7B illustrate an example attachment of the apparatus 104 to the cooling structure 102. FIG. 7B is a detail section view of FIG. 7A. It should be noted that the cooling structure mounting screws 206 may be loosened prior to or after attachment of the apparatus 104. Access to loosening the cooling structure mounting screws 206 may become more difficult after attachment due to the existence of the apparatus 104 and removing the pins 302 from the apparatus 104.

The apparatus 104 is generally attached to the cooling structure 102 by placing the apparatus 104 on top of the cooling structure 102 and pushing down on the apparatus 104 (e.g., towards the base board 202). Pushing down on the apparatus 104 causes the lead in chamfers of the hooks 312 to ride down a side wall of the cooling structure 102. The springs 310 (or the elasticity of the arms 304 if springs 310 are not used) maintain a lateral pressure against the side wall.

Once a suitable indent is encountered (e.g., underneath the cooling structure 102) the springs 310 or the elasticity of the arms 304 causes the hooks 312 to engage the indent. For example, the hooks 312 may engage a cooling structure lower surface 700 of the cooling structure 102. It should be noted that the hooks 312 need not engage the cooling structure 102 towards the bottom of the cooling structure 102. In some implementations, the hooks 312 may engage portions of the cooling structure 102 towards a middle or top of the side wall. The length of the arms 304 may be configured differently depending upon a location of the lift surface (e.g., the cooling structure lower surface 700).

### Example Separation

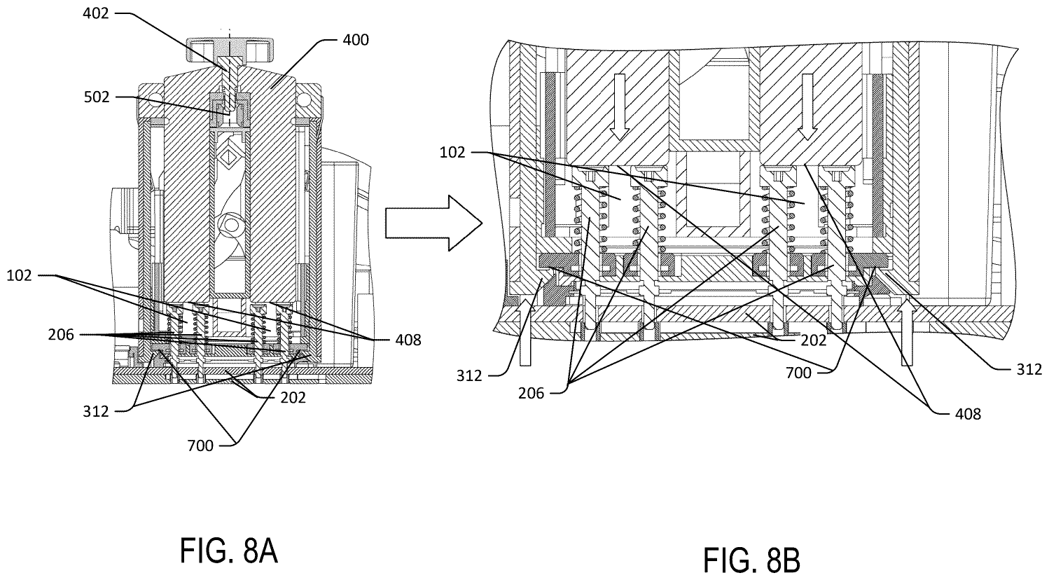

FIGS. 8A and 8B illustrate an example of how the apparatus 104 is used to separate the cooling structure 102 from the base board 202 once installed. FIG. 8A illustrates the apparatus 104 in an initialized position. As shown, the screw 402 is just barely engaged with the threaded hole 502 (e.g., resting on top or only barely threaded therethrough). The hooks 312 are engaged with the cooling structure lower surface 700 (or hovering underneath them), and the abutment surfaces 408 are hovering above the cooling structure mounting screws 206. The apparatus 104 is configured such that, when the apparatus 104 is in the initialized position, a gap exists between the hooks 312 and the cooling structure lower surface 700 and/or between the cooling structure mounting screws 206 and the abutment surfaces 408.

FIG. 8B illustrates the apparatus 104 in the beginning phases of separating the cooling structure 102 from the base board 202. The screw 402 has been threaded into the threaded hole 502 (e.g., rotated) such that any gap that existed between the hooks 312 and the cooling structure lower surface 700 and/or between the cooling structure mounting screws 206 and the abutment surfaces 408 has been eliminated. As the screw 402 continues to thread into the threaded hole 502, the pin body 400 and the body 300/arms 304 are forced towards each other. Because the abutment surfaces 408 are abutted against the tops of the cooling structure mounting screws 206, and because the hooks 312 are abutted against the cooling structure lower surface 700, a relative motion can occur between the body 300/arms 304 and the base board 202. As the body 300/arms 304 move, so does the cooling structure 102. Thus, threading the screw 402 into the threaded hole 502 exerts a force that causes a portion of the cooling structure 102 to separate from the base board 202. As others of the screws 402 (e.g., of other pins 302) are engaged with other threaded holes 502, other portions of the cooling structure 102 are lifted relative to the base board 202. Accordingly, when all of the screws 402 have been threaded into their respective threaded holes 502, the cooling structure 102 may be fully separated from the base board 202. The cooling structure 102 can then be removed from the base board 202 (after removing the cooling structure mounting screws 206).

### Example Method

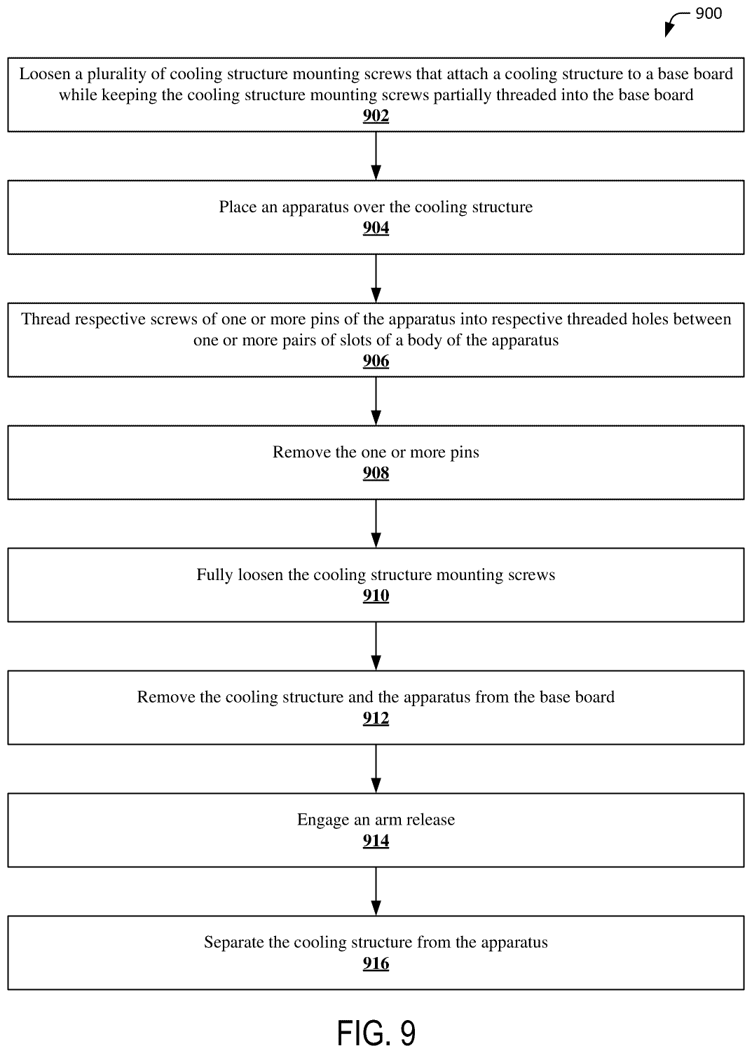

FIG. 9 illustrates an example of a method 900 of removing the cooling structure 102 from the base board 202. Steps may be combined, divided, and/or omitted without departing from the scope of this disclosure.

At 902, a plurality of cooling structure mounting screws that attach a cooling structure to a base board are loosened while keeping the cooling structure mounting screws partially threaded into the base board. For example, the cooling structure mounting screws 206 that attach the cooling structure 102 to the base board 202 may be loosened while keeping the cooling structure mounting screws 206 partially threaded into the base board 202.

At 904, an apparatus is placed over the cooling structure. The placing is effective to cause hooks of arms of the apparatus to engage a cooling structure lower surface of the cooling structure and one or more pairs of slots of a body of the apparatus are aligned with the cooling structure mounting screws. For example, the apparatus 104 may be placed over the cooling structure 102 such that the hooks 312 of the arms 304 engage the cooling structure lower surface 700 of the cooling structure 102 and the pairs of slots 500 are aligned with the cooling structure mounting screws 206.

At 906, respective screws of one or more pins of the apparatus are threaded into respective threaded holes between the one or more pairs of slots. The threading is effective to cause the arms and body of the apparatus to, once abutment surfaces of the pins are abutted against the cooling structure mounting screws, move relative to the mounting screws, which causes a separation of the cooling structure from the base board. For example, the screws 402 may be threaded into the threaded holes 502 effective to cause the arms 304 and the body 300 to, once the abutment surfaces 408 are abutted against the cooling structure mounting screws 206, move relative to the cooling structure mounting screws 206. The relative movement may cause the cooling structure 102 to separate from the base board 202.

At 908, the pins are removed. For example, the screws 402 may be fully unthreaded from the threaded holes 502 and the pins 302 removed from the apparatus 104.

At 910, the cooling structure mounting screws are fully loosened. For example, the cooling structure mounting screws 206 may be fully unthreaded from the base board 202. They may also be removed.

At 912, the cooling structure and the apparatus are removed from the base board. For example, the cooling structure 102 and the apparatus 104 may be removed from the base board 202 as they are attached to each other and the cooling structure mounting screws 206 are no longer keeping the cooling structure 102 attached to the base board 202.

At 914, an arm release is engaged. The engagement is effective to move or deform the arms such that the hooks no longer engage the cooling structure lower surface. For example, the arm release 308 may be engaged effective to move or deform arms 304a-304e away from arms 304 disposed on another side of the body 300. The movement/deformation may cause the hooks 312 to disengage the cooling structure lower surface 700. Another arm release on another side of the body 300 may also be engaged to move or deform another set of arms 304.

At 916, the cooling structure is separated from the apparatus. For example, while the arm releases 308 (e.g., one on each side of the body 300) are engaged, the apparatus 104 may be lifted relative to the cooling structure 102 such that the apparatus 104 is ready for another removal procedure.

### EXAMPLES

Example 1a: An apparatus for separating a cooling structure from a base board of a computing device, the apparatus comprising: a body including: one or more threaded holes; and one or more pairs of slots corresponding to the one or more threaded holes in a one-to-one correspondence, each pair of slots of the one or more pairs of slots: extending through the body; and surrounding a threaded hole of the one or more threaded holes; one or more pins corresponding to the one or more threaded holes in a one-to-one correspondence, each pin of the one or more pins having: a through hole; a screw disposed in the through hole, the screw configured to thread into a threaded hole of the one or more threaded holes; legs configured to be disposed in respective slots of a pair of slots of the one or more pairs of slots; and abutment surfaces at respective ends of the legs configured to abut against cooling structure mounting screws of the cooling structure when the apparatus is installed on the cooling structure and the screw is threaded into the threaded hole; and a plurality of arms coupled to the body, each arm of the plurality of arms including a hook configured to extend underneath the cooling structure when the apparatus is installed on the cooling structure.

Example 2a: The apparatus of example 1a, wherein: the one or more threaded holes include a plurality of threaded holes; and the one or more pins include a plurality of pins.

Example 3a: The apparatus of example 2a, wherein the plurality of threaded holes are arranged in a linear array on the body.

Example 4a: The apparatus of any of examples 1a to 3a, wherein: at least one arm of the plurality of arms is coupled to a side of the body, and at least one other arm of the plurality of arms is coupled to another side of the body that is opposite the side of the body.

Example 5a: The apparatus of any of examples 1a to 4a, wherein the plurality of arms are coupled to the body via respective springs.

Example 6a: The apparatus of any of examples 1a to 4a, wherein the plurality of arms are configured to temporarily deform when the apparatus is installed on the cooling structure.

Example 7a: The apparatus of any of examples 1a to 6a, wherein: the plurality of arms include at least two arms coupled to a side of the body, and the apparatus further includes an arm release configured to move the at least two arms simultaneously.

Example 8a: The apparatus of example 7a, wherein the arm release is further configured to keep the at least two arms from rotating towards one or more other arms on another side of the apparatus past substantially perpendicular to a body top surface of the body.

Example 9a: The apparatus of example 7a, wherein: the arm release is coupled to the at least two arms; the arm release is coupled to the body via one or more springs; and the one or more springs are configured to hold the arms substantially perpendicular to a body top surface of the body.

Example 10a: The apparatus of any of examples 1a to 9a, wherein the hook includes a lead-in chamfer configured to cause a corresponding arm to rotate to deform when the apparatus is installed on the cooling structure.

Example 11a: The apparatus of any of examples 1a to 10a, wherein each of the pins forms a u-shaped structure.

Example 12a: The apparatus of example 11a, wherein the through hole is disposed in a bottom portion of the u-shaped structure.

Example 13a: The apparatus of any of examples 1a to 12a, wherein the screw is a thumb or hand screw.

Example 14a: The apparatus of any of examples 1a to 13a, wherein the abutment surfaces are configured to abut against a plurality of cooling structure mounting screws that are arranged in a linear array.

Example 15a: The apparatus of any of examples 1a to 14a, wherein the arms extend substantially perpendicular to a body top surface of the body.

Example 16a: A method of removing a cooling structure from a base board of a computing device, the method comprising: loosening a plurality of cooling structure mounting screws that attach the cooling structure to the base board while keeping the cooling structure mounting screws partially threaded into the base board; placing an apparatus over the cooling structure such that hooks of arms of the apparatus engage a cooling structure lower surface of the cooling structure and one or more pairs of slots of a body of the apparatus are aligned with the cooling structure mounting screws; threading respective screws of one or more pins of the apparatus into respective threaded holes between the one or more pairs of slots of the body of the apparatus, the threading causing the arms and body of the apparatus to, once abutment surfaces of the pins are abutted against the cooling structure mounting screws, move relative to the mounting screws effective to separate the cooling structure from the base board; removing the one or more pins; fully loosening the cooling structure mounting screws; removing the cooling structure and the apparatus from the base board, engaging an arm release effective to move the arms such that the hooks no longer engage the cooling structure lower surface; and separating the cooling structure from the apparatus.

Example 17a: The method of example 16a, wherein: the one or more pairs of slots include a plurality of pairs of slots; the one or more pins include a plurality of pins.

Example 18a: The method of example 16a or 17a, wherein the placing the apparatus over the cooling structure causes the arms of the apparatus to temporarily rotate or deform away from the cooling structure prior to the hooks engaging the cooling structure lower surface.

Example 19a: A system comprising: a cooling structure including one or more rows of cooling structure mounting locations configured to allow the cooling structure to be mounted to a base board of a computing device; and an apparatus configured to separate the cooling structure from the base board, the apparatus including: a body having: one or more threaded holes corresponding to the one or more rows of cooling structure mounting locations in a one-to-one correspondence; and one or more pairs of slots corresponding to the one or more threaded holes and the one or more rows of cooling structure mounting locations in a one-to-one correspondence, each pair of slots of the one or more pairs of slots: extending through the body; and surrounding a threaded hole of the one or more threaded holes; one or more pins corresponding to the one or more threaded holes and the one or more rows of cooling structure mounting locations in a one-to-one correspondence, each pin of the one or more pins having: a through hole; a screw disposed in the through hole, the screw configured to thread into a threaded hole of the one or more threaded holes; legs configured to: be disposed in respective slots of a pair of slots of the one or more pairs of slots; and extend towards rows of cooling structure mounting locations of the cooling structure mounting locations; and abutment surfaces at ends of the legs configured to abut against cooling structure mounting screws disposed within the one or more rows of cooling structure mounting locations when the cooling structure is mounted to the base board, the apparatus is installed on the cooling structure, and the screw is threaded into the threaded hole; and a plurality of arms coupled to the body, each arm of the plurality of arms including a hook configured to extend underneath the cooling structure when the apparatus is installed on the cooling structure.

Example 20a: The system of example 19a, wherein a configuration of the one or more pairs of slots of the apparatus matches a configuration of the one or more rows of cooling structure mounting locations.

Example 1b: An apparatus for separating a cooling structure from a base board of a computing device, the apparatus comprising: a body; an arm including a first side connected to the body and a second side configured to be detachably connected to the cooling structure; a pin including an abutment surface; and a separation mechanism configured to, in a state where the abutment surface of the pin directly or indirectly abuts the base board, move the body relative to the abutment surface to thereby move the second side of the arm detachably connected to the cooling structure to separate the cooling structure from the base board.

Example 2b: The apparatus according to example 1b, wherein the body defines a slot, wherein the pin is configured to be movably arranged in the slot, and wherein the separation mechanism is configured to, in the state where the abutment surface of the pin directly or indirectly abuts the base board, move the body in a direction away from the abutment surface to thereby move the second side of the arm detachably connected to the cooling structure to separate the cooling structure from the base board.

Example 3b: The apparatus according to example 2b, wherein the body defines a threaded hole substantially extending along a same axis as the slot, wherein the separation mechanism includes a screw configured to thread into the threaded hole of the body, and wherein the screw is configured to, in the state where the abutment surface of the pin directly or indirectly abuts the base board, be rotated in the threaded hole to move the body in the direction away from the abutment surface to thereby move the second side of the arm detachably connected to the cooling structure to separate the cooling structure from the base board.

Example 4b: The apparatus according to example 3b, wherein the pin defines a through hole, wherein in a state where the pin is arranged through the slot of the body, the through hole of the pin is aligned with the threaded hole of the body, and wherein the screw is configured to be disposed in the through hole of the pin and threaded into the threaded hole of the body.

Example 5b: The apparatus according to any of examples 1b to 4b, wherein the body defines a first slot and a second slot, wherein the pin includes a pin body, a first pin leg and a second pin leg, wherein the first pin leg extends away from the pin body and is movably arranged in the first slot of the body, and the second pin leg extends away from the pin body and is movably arranged in the second slot of the body, and wherein in a state where the pin body is arranged on one side of the first slot of the body, the abutment surface is provided on one of the first pin leg or the second pin leg on another side of the first slot of the body.

Example 6b: The apparatus according to example 5b, wherein in the state where the pin body is arranged on the one side of the first slot of the body, the abutment surface is arranged between the first side of the arm connected to the body and the second side of the arm.

Example 7b: The apparatus according to any of examples 1b to 6b, wherein the arm includes a hook provided on the second side of the arm, and wherein the separation mechanism is configured to, in the state where the abutment surface of the pin directly or indirectly abuts the base board, move the body relative to the abutment surface to thereby exert a force against the cooling structure via the hook to separate the cooling structure from the base board.

Example 8b: The apparatus according to any of examples 1b to 7b, further comprising: an arm release configured to detach the second side of the arm from being connected to the cooling structure.

Example 9b: The apparatus according to example 8b, further comprising: a spring configured to bias the second side of the arm towards a position to be detachably connected to the cooling structure, and wherein the arm release is configured to move the second side of the arm away from the position to detach the second side of the arm from being connected to the cooling structure.

Example 10b: The apparatus according to any of examples 1b to 9b, further comprising: a spring configured to bias the second side of the arm towards a position to be detachably connected to the cooling structure, wherein the arm includes: a hook provided on the second side of the arm; and a lead-in chamfer configured to cause the arm to rotate or deform against the bias applied by the spring as the lead-in chamfer abuts an edge of the cooling structure.

Example 11b: The apparatus according to any of examples 1b to 10b, wherein in a state where the second side of the arm is detachably connected to the cooling structure, the arm extends along a length direction such that the abutment surface of the pin abuts a cooling structure mounting screw that mounts the cooling structure to the base board.

Example 12b: A system comprising: a cooling structure configured to thermally contact a base board of a computing device; and an apparatus including: a body; an arm having a first side connected to the body and a second side configured to be detachably connected to the cooling structure; a pin having an abutment surface; and a separation mechanism configured to, in a state where the abutment surface of the pin directly or indirectly abuts the base board, move the body relative to the abutment surface to thereby move the second side of the arm detachably connected to the cooling structure to separate the cooling structure from the base board.

Example 13b: The system according to example 12b, wherein the body defines a slot, wherein the pin is configured to be movably arranged in the slot, and wherein the separation mechanism is configured to, in the state where the abutment surface of the pin directly or indirectly abuts the base board, move the body in a direction away from the abutment surface to thereby move the second side of the arm detachably connected to the cooling structure to separate the cooling structure from the base board.

Example 14b: The system according to example 13b, wherein the body defines a threaded hole substantially extending along a same axis as the slot, wherein the separation mechanism includes a screw configured to thread into the threaded hole of the body, and wherein the screw is configured to, in the state where the abutment surface of the pin directly or indirectly abuts the base board, be rotated in the threaded hole to move the body in the direction away from the abutment surface to thereby move the second side of the arm detachably connected to the cooling structure to separate the cooling structure from the base board.

Example 15b: The system according to example 14b, wherein the pin defines a through hole, wherein in a state where the pin is arranged through the slot of the body, the through hole of the pin is aligned with the threaded hole of the body, and wherein the screw is configured to be disposed in the through hole of the pin and threaded into the threaded hole of the body.

Example 16b: The system according to any of examples 12b to 15b, wherein the body defines a first slot and a second slot, wherein the pin includes a pin body, a first pin leg and a second pin leg, wherein the first pin leg extends away from the pin body and is movably arranged in the first slot of the body, and the second pin leg extends away from the pin body and is movably arranged in the second slot of the body, and wherein in a state where the pin body is arranged on one side of the first slot of the body, the abutment surface is provided on one of the first pin leg and the second pin leg on another side of the first slot of the body.

Example 17b: The system according to example 16b, wherein in the state where the pin body is arranged on the one side of the first slot of the body, the abutment surface is arranged between the first side of the arm connected to the body and the second side of the arm.

Example 18b: The system according to any of examples 12b to 17b, wherein the arm includes a hook provided on the second side of the arm, and wherein the separation mechanism is configured to, in the state where the abutment surface of the pin directly or indirectly abuts the base board, move the body relative to the abutment surface to thereby exert a force against the cooling structure via the hook to separate the cooling structure from the base board.

Example 19b: The system according to any of examples 12b to 18b, further comprising: an arm release configured to detach the second side of the arm from being connected to the cooling structure.

Example 20b: A method of operating an apparatus for separating a cooling structure from a base board of a computing device, the apparatus comprising a body, an arm comprising a first side connected to the body and a second side configured to be detachably connected to the cooling structure, a pin comprising an abutment surface, and a separation mechanism, the method comprising: connecting the second side of the arm to the cooling structure; moving the abutment surface of the pin to directly or indirectly abut the base board; and in a state where the abutment surface of the pin directly or indirectly abuts the base board, moving, by the separation mechanism, the body relative to the abutment surface to thereby move the second side of the arm detachably connected to the cooling structure to separate the cooling structure from the base board.

### CONCLUSION

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The various embodiments were chosen and described in order to best explain the principles of the invention and the practical application, and to enable others of ordinary skill in the art to understand the invention for various embodiments with various modifications as are suited to the particular use contemplated.

What is claimed is:

1. An apparatus for separating a cooling structure from a base board of a computing device, the apparatus comprising:
a body;
an arm including a first side connected to the body and a second side configured to be detachably connected to the cooling structure;
a pin including an abutment surface; and
a separation mechanism configured to, in a state where the abutment surface of the pin directly or indirectly abuts the base board, move the body relative to the abutment surface to thereby move the second side of the arm detachably connected to the cooling structure to separate the cooling structure from the base board.

2. The apparatus according to claim 1,
wherein the body defines a slot,
wherein the pin is configured to be movably arranged in the slot, and
wherein the separation mechanism is configured to, in the state where the abutment surface of the pin directly or indirectly abuts the base board, move the body in a direction away from the abutment surface to thereby move the second side of the arm detachably connected to the cooling structure to separate the cooling structure from the base board.

3. The apparatus according to claim 2,
wherein the body defines a threaded hole substantially extending along a same axis as the slot,
wherein the separation mechanism includes a screw configured to thread into the threaded hole of the body, and
wherein the screw is configured to, in the state where the abutment surface of the pin directly or indirectly abuts the base board, be rotated in the threaded hole to move the body in the direction away from the abutment surface to thereby move the second side of the arm detachably connected to the cooling structure to separate the cooling structure from the base board.

4. The apparatus according to claim 3,
wherein the pin defines a through hole,
wherein in a state where the pin is arranged through the slot of the body, the through hole of the pin is aligned with the threaded hole of the body, and
wherein the screw is configured to be disposed in the through hole of the pin and threaded into the threaded hole of the body.

5. The apparatus according to claim 1,
wherein the body defines a pair of slots including a first slot and a second slot,
wherein the pin includes a pin body including a first leg, a second leg, and a bridge portion,
wherein the first leg extends away from the bridge portion and is movably arranged in the first slot of the pair of slots, and the second leg extends away from the bridge portion and is movably arranged in the second slot of the pair of slots, and
wherein in a state where the bridge portion is arranged on one side of the pair of slots, the abutment surface is provided on one of the first leg or the second leg on another side of the pair of slots.

6. The apparatus according to claim 5,
wherein in the state where the bridge portion is arranged on the one side of the pair of slots, the abutment surface is arranged between the first side of the arm connected to the body and the second side of the arm.

7. The apparatus according to claim 1,
wherein the arm includes a hook provided on the second side of the arm, and
wherein the separation mechanism is configured to, in the state where the abutment surface of the pin directly or indirectly abuts the base board, move the body relative to the abutment surface to thereby exert a force against the cooling structure via the hook to separate the cooling structure from the base board.

8. The apparatus according to claim 1, further comprising:
an arm release configured to detach the second side of the arm from being connected to the cooling structure.

9. The apparatus according to claim 8, further comprising:
a spring configured to bias the second side of the arm towards a position to be detachably connected to the cooling structure, and
wherein the arm release is configured to move the second side of the arm away from the position to detach the second side of the arm from being connected to the cooling structure.

10. The apparatus according to claim 1, further comprising:
a spring configured to apply a bias to the second side of the arm towards a position to be detachably connected to the cooling structure,
wherein the arm includes:
a hook provided on the second side of the arm; and
a lead-in chamfer configured to cause the arm to rotate or deform against the bias applied by the spring as the lead-in chamfer abuts an edge of the cooling structure.

11. The apparatus according to claim 1,
wherein in a state where the second side of the arm is detachably connected to the cooling structure, the arm extends along a length direction such that the abutment surface of the pin abuts a cooling structure mounting screw that mounts the cooling structure to the base board.

12. A system comprising:
a cooling structure configured to thermally contact a base board of a computing device; and
an apparatus including:
a body;
an arm having a first side connected to the body and a second side configured to be detachably connected to the cooling structure;
a pin having an abutment surface; and
a separation mechanism configured to, in a state where the abutment surface of the pin directly or indirectly abuts the base board, move the body relative to the abutment surface to thereby move the second side of the arm detachably connected to the cooling structure to separate the cooling structure from the base board.

13. The system according to claim 12,
wherein the body defines a slot,
wherein the pin is configured to be movably arranged in the slot, and
wherein the separation mechanism is configured to, in the state where the abutment surface of the pin directly or indirectly abuts the base board, move the body in a direction away from the abutment surface to thereby move the second side of the arm detachably connected to the cooling structure to separate the cooling structure from the base board.

14. The system according to claim 13,
wherein the body defines a threaded hole substantially extending along a same axis as the slot,
wherein the separation mechanism includes a screw configured to thread into the threaded hole of the body, and
wherein the screw is configured to, in the state where the abutment surface of the pin directly or indirectly abuts the base board, be rotated in the threaded hole to move the body in the direction away from the abutment surface to thereby move the second side of the arm detachably connected to the cooling structure to separate the cooling structure from the base board.

15. The system according to claim 14,
wherein the pin defines a through hole,
wherein in a state where the pin is arranged through the slot of the body, the through hole of the pin is aligned with the threaded hole of the body, and
wherein the screw is configured to be disposed in the through hole of the pin and threaded into the threaded hole of the body.

16. The system according to claim 12,
wherein the body defines a pair of slots including a first slot and a second slot,
wherein the pin includes a pin body including a first leg, a second leg, and a bridge portion,
wherein the first leg extends away from the bridge portion and is movably arranged in the first slot of the pair of slots, and the second leg extends away from the bridge portion and is movably arranged in the second slot of the pair of slots, and
wherein in a state where the bridge portion is arranged on one side of the pair of slots, the abutment surface is provided on one of the first leg or the second leg on another side of the pair of slots.

17. The system according to claim 16,
wherein in the state where the pin body is arranged on the one side of the first slot of the body, the abutment surface is arranged between the first side of the arm connected to the body and the second side of the arm.

18. The system according to claim 12,
wherein the arm includes a hook provided on the second side of the arm, and
wherein the separation mechanism is configured to, in the state where the abutment surface of the pin directly or indirectly abuts the base board, move the body relative to the abutment surface to thereby exert a force against the cooling structure via the hook to separate the cooling structure from the base board.

19. The system according to claim 12, further comprising:
an arm release configured to detach the second side of the arm from being connected to the cooling structure.

20. A method of operating an apparatus for separating a cooling structure from a base board of a computing device, the apparatus comprising a body, an arm comprising a first side connected to the body and a second side configured to be detachably connected to the cooling structure, a pin comprising an abutment surface, and a separation mechanism, the method comprising:
connecting the second side of the arm to the cooling structure;
moving the abutment surface of the pin to directly or indirectly abut the base board; and
in a state where the abutment surface of the pin directly or indirectly abuts the base board, moving, by the separation mechanism, the body relative to the abutment surface to thereby move the second side of the arm detachably connected to the cooling structure to separate the cooling structure from the base board.
